(19) United States
(12) Patent Application Publication
(10) Pub. No.: US 2026/0195586 A1
(43) Pub. Date: Jul. 9, 2026

(54) MACHINE LEARNING MODEL TRAINING METHOD AND PREDICTION METHOD FOR CD-SEM MEASUREMENT, AND COMPUTING DEVICE

(71) Applicant: Institute of Semiconductors, Guangdong Academy of Sciences, Guangdong (CN)

(72) Inventors: Zhuming Liu, Guangdong (CN); Delong Chen, Guangdong (CN); Heming WU, Guangdong (CN); Jinguo Ge, Guangdong (CN); Xingwen Chen, Guangdong (CN); Yanan Zhu, Guangdong (CN); Zitong Zhang, Guangdong (CN); Zhitao Chen, Guangdong (CN)

(73) Assignee: Institute of Semiconductors, Guangdong Academy of Sciences, Guangdong (CN)

(21) Appl. No.: 19/220,661

(22) Filed: May 28, 2025

(30) Foreign Application Priority Data
Jan. 3, 2025 (CN) 202510010170.6

(51) Int. Cl. G06N 3/08; G01B 15/00; H01J 37/28

(52) U.S. Cl. CPC G06N 3/08; G01B 15/00; H01J 37/28

(57) ABSTRACT

The present disclosure discloses a machine learning model training method and parameter prediction method for CD-SEM measurement. The training method includes: acquiring a data set, where the data set includes at least one data group with proximity effect characteristics, and the SE signal group in the data group with proximity effect characteristics is a secondary electron signal generated by performing electron beam scanning on a geometric structure with neighboring structures; and training a pre-built neural network model by taking the SE signal group in the data group of the data set as input and the standard data in the same data group as output to obtain a parameter prediction model configured to predict parameter in CD-SEM measurement. According to the present disclosure, since there is no need to modify a CD-SEM hardware structure, there is no problem of hardware complexity or problem of reliability influence.

### CROSS-REFERENCE TO RELATED APPLICATION

This application claims the priority of Chinese patent application No. 202510010170.6, filed on Jan. 3, 2025, which application is hereby incorporated herein by reference.

### TECHNICAL FIELD

The present disclosure relates to the technical field of semiconductor measurement, and in particular, to a machine learning model training method for CD-SEM measurement, a method for parameter prediction using a parameter prediction model obtained by training, and a computing device.

### BACKGROUND

Critical dimension scanning electron microscope (CD-SEM) is a key technology for measuring a pattern structure on a wafer or mask in semiconductor industry. With the development of integrated circuit industry, the dimension of a device structure becomes smaller and smaller, and the device structure also evolves to a three-dimensional structure, which makes CD-SEM face greater challenges, especially in three-dimensional (3D) metrology. The height and aspect ratio of the device structure are important parameters for characterizing three dimensions. However, CD-SEM cannot directly measure these important parameters at present, making it very inconvenient to acquire these parameters.

The following several measurement methods for measuring the height and aspect ratio exist in the prior art in this field: 1. Using two or more images with different incident electron beam angles. However, this method increases the complexity of a measurement device and consumes more time to collect images. 2. Using an exponential function to associate a BSE (Back Scattered Electron) signal intensity with the depth of an HAR (High Aspect Ratio) hole. However, this method usually requires CD-SEM to operate in a high accelerating voltage state, which is easy to damage a sample. In addition, the quality of a detection image obtained by means of BSE is lower as compared with a secondary electron (SE) image. 3. Obtaining a multi-angle incidence diagram of electron beams by tilting a sample workpiece table. However, the mechanical movement of the workpiece table brings instability and strict alignment problems. For example, in order to measure the height and aspect ratio, Applied Materials developed and realized electron beam tilt on its product V4i+ CD-SEM, for height measurement. In this product scheme, two groups of images may be obtained after light beams with a low tilt angle (5°) and light beams with a high tilt angle (14°) are calibrated, which are used to measure an edge width of a sidewall to calculate the height. However, the method adopted by the product V4i+ CD-SEM of Applied Materials will complicate CD-SEM hardware and bring reliability problems.

### SUMMARY

Embodiments of the present disclosure provide a machine learning model training method and prediction method for CD-SEM measurement, and a computing device, to solve the problem that it is difficult to measure aspect ratio and height parameters of a device structure in the prior art.

According to a first aspect of the present disclosure, a machine learning model training method for CD-SEM measurement is provided. The method is performed by a computer device, and a trained machine learning model is called a parameter prediction model configured to perform parameter prediction in CD-SEM measurement. The training method includes:
acquiring a data set, where the data set includes at least one data group with proximity effect characteristics, each data group includes standard data and an SE signal group, the standard data includes aspect ratio data and/or height data, and the SE signal group in the data group with proximity effect characteristics is a secondary electron signal generated by performing electron beam scanning on a geometric structure with neighboring structures; and
training a pre-built neural network model by taking the SE signal group in the same data group of the data set as input and the standard data in the same data group as output to obtain a parameter prediction model configured to predict aspect ratio data and/or height data in CD-SEMmeasurement.

By means of the technical scheme of the present application, a machine learning model, mainly a neural network model, is adopted as a basic model for training, and in the machine learning model training method, a built neural network model is trained by taking the SE signal group as input and the standard data corresponding to the SE signal group, i.e. corresponding aspect ratio data and/or height data as output, so that the obtained parameter prediction model can predict aspect ratio data and/or height data of a corresponding device structure based on SE signals. Compared with the method in the prior art, in the method of the present application, there is no need to modify a hardware structure of a CD-SEM, thus avoiding the problem of complicating the hardware structure of the CD-SEM and also avoiding the problem of affecting the reliability of the hardware structure of the CD-SEM, and there is no need to adjust operation parameters of the CD-SEM, so that a sample will not be damaged and the quality of a detection mage will not be affected. Moreover, the data set adopted when training the parameter prediction model of the present disclosure is a data group with proximity effect characteristics. Thus, the parameter prediction model obtained in an embodiment of the present disclosure can fully consider parameters related to the proximity effect characteristics when performing prediction, so that the predicted parameters are more in line with the actual application scenarios and the accuracy is higher. Upon accuracy testing, when the built parameter prediction model of the present disclosure is used to predict aspect ratios and heights, the mean relative error between the obtained aspect ratio prediction values and the standard value is 2.4%, the percentage of prediction cases with an error within 20% is 100.0%, the mean relative error between the obtained height prediction values and the standard value is 1.9%, and the percentage of prediction cases with an error within 10% is 99.5%.

In some implementations, the neural network model is built by:
building a network architecture of the neural network model based on an Identity block and a Dense block; and
building, according to the proposed network architecture, the neural network model using Keras library, where when building, the model is compiled using a compile function, MSE is specified as the loss function, Adam is specified as a neural network optimizer, and MSE is specified as the metrics function.

Therefore, a fully connected layer is adopted instead of a convolution layer and a pooling layer in the network architecture of the parameter prediction model of the present application. Thus, compared with a traditional residual network which is more suitable for image processing, the model architecture of the present application is more suitable for nonlinear regression, so that a prediction result of a parameter prediction model obtained by training the neural network model is more accurate and the training efficiency is higher.

In some implementations, the network architecture of the built neural network model is set up as composed of two basic blocks, a batch normalization layer, a fully connected layer, and a linear activation function which are connected sequentially, where each basic block is formed by connecting two Identity blocks sequentially after one Dense block;
the Identity block includes three basic units which are connected sequentially, where each basic unit is formed by connecting a fully connected layer, a batch normalization layer, and a ReLU activation function sequentially, and a Dropout layer is inserted after the second basic unit; and
the Dense block includes three basic units which are connected sequentially, where a Dropout layer is inserted after the second basic unit, and a residual path unit is connected additionally after each of the first basic unit and the second basic unit, where the residual path unit consists of a fully connected layer and a batch normalization layer which are stacked sequentially, and a result between the output of the residual path unit and the batch normalization layer and ReLU activation function of the third basic unit of the Dense block is configured to perform a tensor summation operation.

In this way, the network architecture may be further suitable for nonlinear regression, and the accuracy of prediction results and training efficiency may be improved.

In some implementations, the data set is obtained by performing SEM simulation imaging on a simulation-built geometric structure with neighboring structures, where the standard data in each data group of the data set is obtained based on parameter information about the simulation-built geometric structure, and the SE signal is obtained based on parameter information about the simulation imaging.

Therefore, by means of the technical scheme of the present disclosure, training costs can be greatly reduced by the simulation-built structure instead of the actual product for testing. Since the parameters of the simulation-built structure are highly controllable, device structures with different parameter combinations can be provided as data sets, to provide different types of data samples for model training, which is helpful to improve the prediction accuracy of the parameter prediction model obtained by training.

In some implementations, the data set includes a training set and a test set which are obtained by performing random number partitioning on a plurality of data groups of the data set; and
when training, the built neural network model is trained using part data groups of the training set to acquire model parameters, and the acquired model parameters are optimized using the rest data groups of the training set.

By partitioning the data set, the model may be trained and optimized using the training set, and the prediction accuracy of the model parameters may be determined using the test set to ensure the accuracy of the parameter prediction model obtained by training. Meanwhile, the data set may be disordered, so that the data groups in the data set are no longer coherent, thus reducing the consideration of data coherence in training of the parameter prediction model, making the finally obtained parameter prediction model more suitable for more different scenarios, and improving the prediction accuracy of the parameter prediction model. As an example, 90% of the data groups in the whole training set can be used to acquire model parameters, and the rest 10% data groups can be used to optimize the model parameters.

In some implementations, the training a pre-built neural network model by taking the SE signal group in the same data group of the data set as input and the standard data in the same data group as output to obtain a parameter prediction model includes:
training the pre-built neural network model by taking the SE signal group in the part data groups of the training set as input and the standard data in the same data group as output to obtain a first model parameter;
updating the neural network model according to the first model parameter to obtain a first neural network model;
inputting the SE signal group in the rest data groups of the training set into the first neural network model, and acquiring a prediction result of the first neural network model on the input SE signal group; and
evaluating an error between the prediction result and the standard data in the corresponding data group using a loss function value, and optimizing the first neural network model according to the neural network optimizer and the error to obtain a parameter prediction model.

Therefore, the neural network model may be iteratively optimized, and the training effect may be monitored in real time by taking the MSE specified by the loss function as an indicator in the training process, so as to improve the accuracy of the finally obtained parameter prediction model.

In some implementations, before training the built neural network model, the method further includes: pre-processing the data set, including normalizing the data set.

Normalization may avoid the interference of the bias of a simulator or electron microscope itself on the data in the data set. Furthermore, data normalization may solve the problem of inconsistent scales of different features, making the influence of different features on the model more balanced. In addition, normalization may also prevent the problem of gradient disappearance or explosion, thus accelerating the convergence speed of the model.

In some implementations, the training method further includes: determining prediction accuracy of the parameter prediction model according to the data set and the parameter prediction model, including:
inputting the SE signal group in the data group of the test set as input into the parameter prediction model, and acquiring predicted data output by the parameter prediction model; and
determining the prediction accuracy of the parameter prediction model through the metrics function according to the predicted data and the standard data in the data group where the input SE signal group is located.

Therefore, the prediction accuracy of the parameter prediction model obtained by training may be further determined to service as an accuracy reference.

According to a second aspect of the present disclosure, a parameter prediction model training apparatus for CD-SEM measurement is provided. The apparatus includes:
a data acquisition module, configured to acquire a data set, where the data set includes at least one data group with proximity effect characteristics, each data group includes standard data and an SE signal group, the standard data includes aspect ratio data and/or height data, and the SE signal group in the data group with proximity effect characteristics is a secondary electron signal generated by performing electron beam scanning on a geometric structure with neighboring structures; and
a training module, configured to train a pre-built neural network model by taking the SE signal group in the same data group of the data set as input and the standard data in the same data group as output to obtain a parameter prediction model configured to predict aspect ratio data and/or height data in CD-SEM measurement.

According to a third aspect of the present disclosure, a parameter prediction method for CD-SEM measurement is provided. The method predicts an aspect ratio and/or a height of a device structure using the parameter prediction model obtained by means of the parameter prediction model building method for CD-SEM measurement described in the above first aspect and an SE signal of the device structure.

According to a fourth aspect of the present disclosure, a parameter prediction system for CD-SEM measurement is provided. The system includes:

a prediction module, configured to predict an aspect ratio and/or a height of a device structure according to an SE signal of the device structure and the parameter prediction model obtained by means of the parameter prediction model building method for CD-SEM measurement described in the above first aspect.

According to a fifth aspect of the present disclosure, a computing device is provided. The device includes:
a memory, configured to store executable instructions; and
a processor, configured to execute the executable instructions stored in the memory, where the executable instructions, when executed by the processor, perform the following machine learning model training method:
acquiring a data set, where the data set includes at least one data group with proximity effect characteristics, each data group includes standard data and an SE signal group, the standard data includes aspect ratio data and/or height data, and the SE signal group in the data group with proximity effect characteristics is a secondary electron signal generated by performing electron beam scanning on a geometric structure with neighboring structures; and
training a pre-built neural network model by taking the SE signal group in the same data group of the data set as input and the standard data in the same data group as output to obtain a parameter prediction model configured to predict aspect ratio data and/or height data in CD-SEMmeasurement.

According to a sixth aspect of the present disclosure, a parameter prediction method for CD-SEM measurement performed by a computer device is provided. The method includes:
inputting an SE signal of a device structure to be measured into a pre-trained machine learning model, and acquiring a prediction result output by the machine learning model, where the machine learning model is a parameter prediction model obtained by training by using the method described in the first aspect above, and the prediction result includes a prediction result of an aspect ratio and/or a height of the device structure.

According to a seventh aspect of the present disclosure, a computing device is provided. The device includes:
a memory, configured to store executable instructions; and
a processor, configured to execute the executable instructions stored in the memory, wherein the executable instructions, when executed by the processor, perform the following parameter prediction method for CD-SEM measurement:
inputting an SE signal of a device structure to be measured into a pre-trained machine learning model, and acquiring a prediction result output by the machine learning model, where the machine learning model is a parameter prediction model obtained by training by using the method described in the first aspect above, and the prediction result includes a prediction result of an aspect ratio and/or a height of the device structure.

### BRIEF DESCRIPTION OF THE DRAWINGS

In order to more clearly explain the technical schemes in the embodiments of the present disclosure, the drawings to be used in the description of the embodiments will be briefly introduced below. Obviously, the drawings in the following description below are some embodiments of the present disclosure. Those of ordinary skill in the art may also obtain other drawings according to these drawings without creative efforts.

FIG. 1 is a flowchart of a machine learning model training method for CD-SEM measurement according to an implementation of the present disclosure;

FIG. 2 is an overall structural schematic diagram of a simulation-built geometric structure when a data set is acquired in a machine learning model training method for CD-SEM measurement according to an implementation of the present disclosure;

FIG. 3 is a sectional structural schematic diagram of a simulation-built geometric structure when a data set is acquired in a machine learning model training method for CD-SEM measurement according to an implementation of the present disclosure;

FIG. 4 is a comparison diagram schematically showing SE signals of geometric structures with different structure bottom widths;

FIG. 5 is a comparison diagram schematically showing SE signals of geometric structures with different sidewall angles;

FIG. 6 is comparison diagram schematically showing SE signals of geometric structure with different heights;

FIG. 7 is a flowchart of step S11 in a machine learning model training method for CD-SEM measurement according to an implementation of the present disclosure;

FIG. 8 is a schematic diagram of a principle frame of a network architecture of a neural network model in a machine learning model training method for CD-SEM measurement according to an implementation of the present disclosure;

FIG. 9 is a flowchart of step S12 in a machine learning model training method for CD-SEM measurement according to an implementation of the present disclosure;

FIG. 10 is a flowchart of a machine learning model training method for CD-SEM measurement according to another implementation of the present disclosure;

FIG. 11 is a flowchart schematically showing step S13 in a machine learning model training method for CD-SEM measurement according to the implementation shown in FIG. 10;

FIG. 12 is a scatter diagram schematically showing aspect ratios in standard data and aspect ratios in predicted data;

FIG. 13 is a distribution diagram schematically showing relative errors between aspect ratios in standard data and aspect ratios in predicted data;

FIG. 14 is a scatter diagram schematically showing heights in standard data and heights in predicted data;

FIG. 15 is a distribution diagram schematically showing relative errors between heights in standard data and heights in predicted data;

FIG. 16 is a schematic block diagram schematically showing a machine learning model training apparatus for CD-SEM measurement according to an implementation of the present disclosure;

FIG. 17 is a flowchart schematically showing a parameter prediction method for CD-SEM measurement according to an implementation of the present disclosure; and

FIG. 18 is a structural schematic diagram schematically showing an embodiment of a computing device of the present disclosure.

### DETAILED DESCRIPTION

In order to make the objectives, technical schemes and advantages of the embodiments of the present disclosure clearer, the technical schemes in the embodiments of the present disclosure will be clearly and completely described below in conjunction with the drawings in the embodiments of the present disclosure. Apparently, the described embodiments are only some but not all of the embodiments of the present disclosure. On the basis of the embodiments in the present disclosure, all other embodiments obtained by those of ordinary skill in the art without creative efforts shall fall within the protection scope of the present disclosure.

It should be noted that the embodiments in the present application and the features in the embodiments may be combined with each other without conflict.

Finally, it should be noted that relational terms such as first and second herein are only used to distinguish one entity or operation from another entity or operation, and do not necessarily require or imply any such actual relationship or order between these entities or operations. Moreover, the terms “including” and “containing” include not only those elements, but also other elements not explicitly listed, or elements inherent to such process, method, article or device. Under the condition of no more limitation, the elements defined by a sentence “include . . . ” do not exclude additional identical elements in the process, method, article or device which includes the elements.

The present disclosure will be further described in detail in conjunction with the drawings.

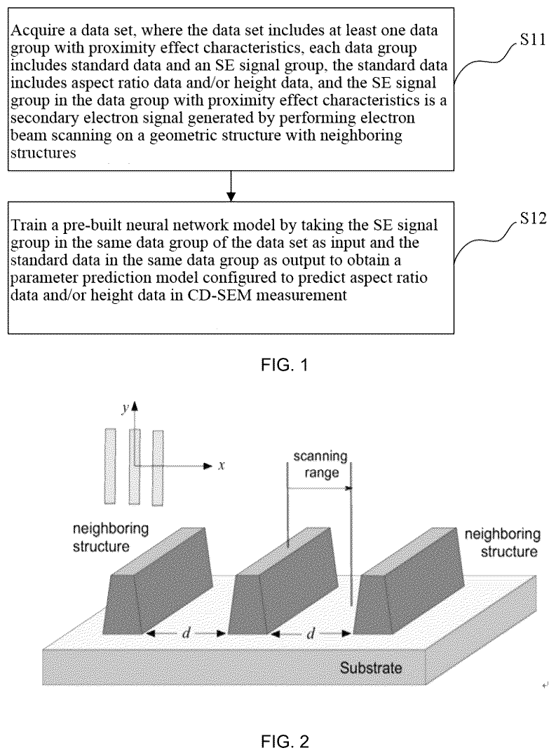

FIG. 1 schematically shows an overall step flow of a machine learning model training method for CD-SEM measurement according to an implementation of the present disclosure. The method may be performed by a computing device such as a computer and a server, to train a machine learning model for CD-SEM measurement by means of the method. In an embodiment of the present disclosure, the trained machine learning model for CD-SEM measurement is called a parameter prediction model. Referring to FIG. 1, the machine learning model training method for CD-SEM measurement of the present disclosure includes:
step S11, Acquire a data set, where the data set includes at least one data group with proximity effect characteristics, each data group includes standard data and an SE signal group, the standard data includes aspect ratio data and/or height data, and the SE signal group in the data group with proximity effect characteristics is a secondary electron signal generated by performing electron beam scanning on a geometric structure with neighboring structures; and
step S12, Train a pre-built neural network model by taking the SE signal group in the same data group of the data set as input and the standard data in the same data group as output to obtain a parameter prediction model configured to predict aspect ratio data and/or height data in CD-SEM measurement.

In step S11, the data set includes several data groups, and each data group represents a structure parameter of a device structure and an SE signal obtained by performing SEM simulation imaging on the device structure. The structure parameter of the device structure may be an aspect ratio and/or a height, that is, each data group includes standard data and a corresponding SE signal group, and the standard data includes aspect ratio data and/or height data. In particular, in an embodiment of the present disclosure, at least one data group is a data group with proximity effect characteristics, and the data group with proximity effect characteristics means that the SE signal group therein is a secondary electron signal generated by performing electron beam scanning on a geometric structure with neighboring structures, that is, such SE signal group considers the influence of proximity effect characteristics. Specifically, the data set may be represented by a two-dimensional array. In this case, each row of the two-dimensional array represents a data group, the first two columns of each row represent standard data, and remaining columns from the third column represent SE signal groups, thus realizing one-to-one correspondence between the SE signals and aspect ratio data and height data corresponding thereto.

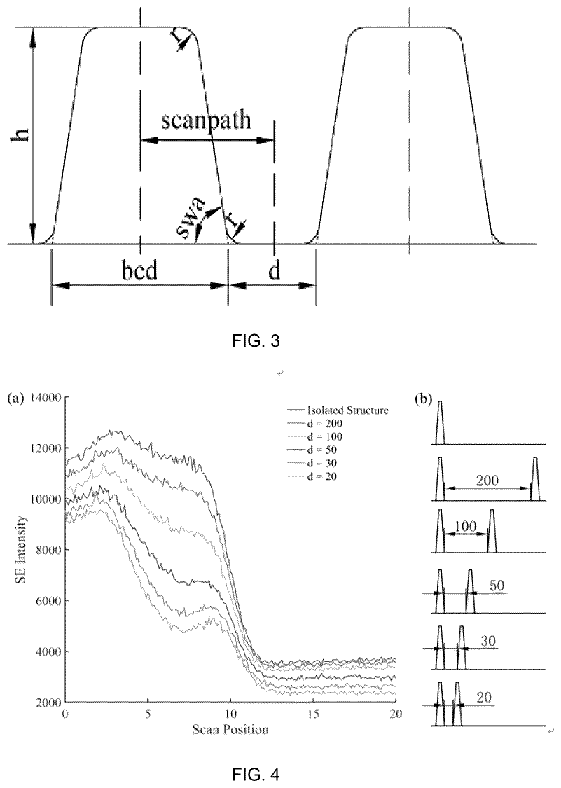

In some possible implementations, each data group in the data set may be obtained by performing measurement and test using an actual sample. Preferably, the data group with proximity effect characteristics in an embodiment of the present disclosure may be obtained by performing SEM simulation imaging on a simulation-built geometric structure with neighboring structures. Referring to FIG. 2 and FIG. 3, FIG. 2 and FIG. 3 are an overall structural schematic diagram and a sectional structural schematic diagram which schematically show a simulation-built geometric structure with neighboring structures, where h represents a structure height, bcd represents a structure bottom width, swa represents a sidewall angle, r represents a top or bottom round angle, d represents a distance between the neighboring structures, and scanpath represents a scan path of an electron probe. Generally speaking, it can be considered that an arc line of the round angle is tangent to a neighboring edge, so that the position of the arc line of the round angle may be obtained according to the sidewall angle swa and the round angle r. In CD-SEM measurement, the influence of proximity effects cannot be ignored. Therefore, by means of the scheme of the present application, the performance of proximity effects of different structure distances, sidewall angles and heights will be analyzed to acquire a data group that fully considers the performance of proximity effects as a data set, which can effectively improve the prediction accuracy of the parameter prediction model obtained by training. During analysis, the benchmark structure parameters used in the scheme of the present disclosure are as follows: bcd=20, swa=86°, d=20, and h=100. When the value of d, swa, or h is changed, other parameters remain unchanged. All scanning signal contours mentioned above are derived from SE signals. For example, the data set derived in an embodiment of the present disclosure includes 5906 ata groups, that is, 5906 rows of data groups, where the first column represents aspect ratio data, the second column represents height data, and all subsequent columns represent SE signals respectively, with a total number of 245 columns. The aspect ratio data and the height data are directly acquired from corresponding parameter information about the simulation-built geometric structure, and the SE signals are derived from the SE signal parameter information obtained by performing SEM simulation imaging on the simulation-built corresponding geometric structure.

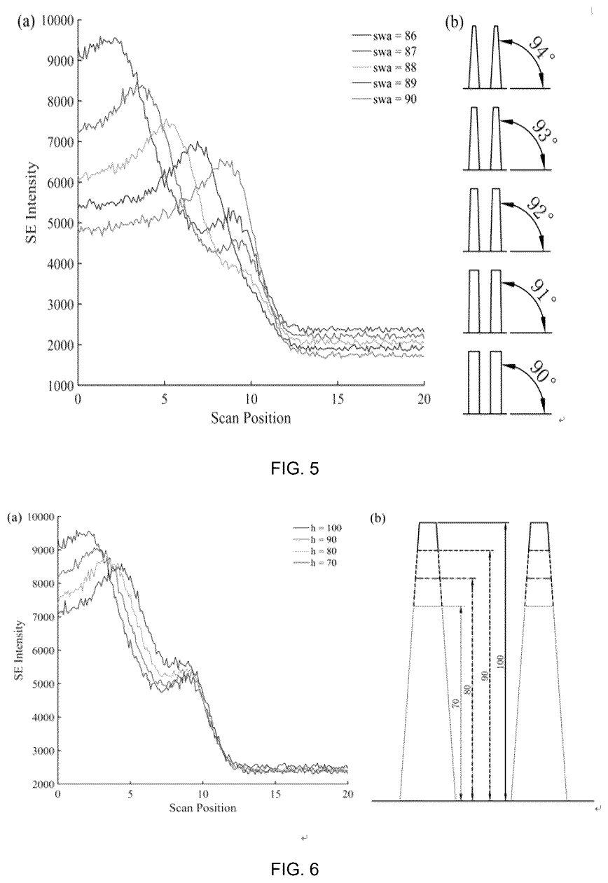

FIG. 4 to FIG. 6 are comparison diagrams schematically showing SE signals corresponding to changes in different parameters. FIG. 4 is a comparison diagram of SE signals of geometric structures with different structure bottom widths bcd. Specifically, the values of d in these structures are set to 20 nm, 30 nm, 50 nm, 100 nm, and 200 nm, respectively. As can be seen from FIG. 4 that the SE signal generally shows a weakening trend as the distance between line structures decreases, which is due to the fact that when the distance between neighboring lines is shorter, the SE signal is more easily blocked, that is, the proximity effect is more obvious. FIG. 5 is a comparison diagram of SE signals of geometric structures with different sidewall angles swa. Specifically, the values of swa in these structures are 86°, 87°, 88°, 89°, and 90°, respectively. As can be seen from FIG. 5 that the peak of the SE signal decreases with the increase in swa value, which is due to the increased possibility of the SE signals being blocked by neighboring structures. The peak of the SE signal shifts to the right with the increase in swa, which is due to the increase in width of the upper edge. In addition, when swa is relatively small, a second peak will appear in the signal curve. When swa increases to 88°, the second peak is almost invisible. FIG. 6 is a comparison diagram of SE signals of geometric structures with different heights. The values of h in these structures are 70 nm, 80 nm, 90 nm, and 100 nm, respectively. As can be seen from FIG. 6 that the peak of the SE signal decreases with the decrease in height, and the peak shifts to the right in position, which is due to the fact that different heights will lead to different upper groove widths when the swa is fixed. In addition, it can be found that a path between the upper edge and the lower edge of SE signals from both sides increases with the decrease in height, which is due to the fact that the decrease in height makes the neighboring structures block the SE signals to a lesser extent. Furthermore, in the present disclosure, by acquiring a data set with proximity effect characteristics for training, the influence of parameters related to the proximity effect characteristics on the prediction result may be comprehensively considered, so that predicted parameters are more in line with the actual application scenarios and the accuracy is higher.

In some implementations, the data set may be split to form a training set and a test set, where the training set and the test set are obtained by performing random number partitioning on a plurality of data groups of the data set. For example, random number partitioning is performed to partition the data set into a training set that accounts for 90% and a test set that accounts for the remaining 10%. Further, the training set may also be split to form two child sets, and it also can be performed by random number partitioning. When training, part data groups of the training set will be selected as a first child set to train the built neural network model, for example 90%, and the rest data groups of the training set, for example 10%, will be used as a validation set to optimize the model, to simplify the description, the rest data groups of the training set will be referred to as validation set in this disclosure. And the prediction accuracy of a parameter prediction model is determined using the test set after the parameter prediction model is obtained by training. It can be understood that in the present disclosure, the data set is obtained by performing SEM simulation imaging on a simulation-built geometric structure with neighboring structures, so that there will be certain coherence among the data groups of the data set. In this way, the neural network model may take the coherence into consideration during training, thus affecting the prediction accuracy of the parameter prediction model obtained by training. The whole data set is disordered in a manner of random number partitioning, so that the training set used for training can no longer be coherent, thus reducing the consideration of coherence in training of the neural network model, making the finally obtained parameter prediction model more suitable for more different scenarios, and improving the prediction accuracy of the parameter prediction model. Moreover, by acquiring the test set in this way, it is not necessary to additionally acquire a data set for test, and thus the overall training and testing efficiency is improved.

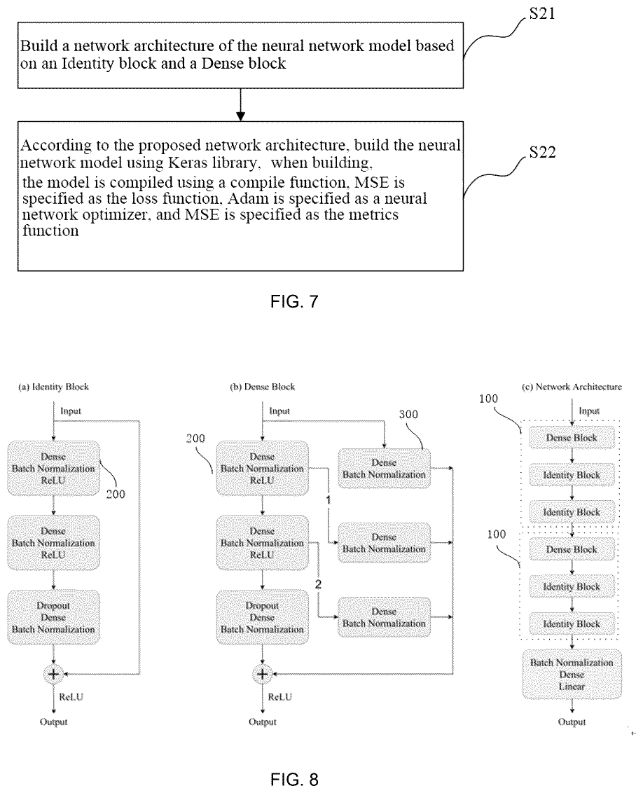

In step S12, the pre-built neural network is built by taking the network architecture built based on the Identity block and the Dense block as a basis. FIG. 7 schematically shows a method flow of pre-building a neural network model in a machine learning model training method for CD-SEM measurement according to an implementation of the present disclosure. Referring to FIG. 7, step S12 may be specifically implemented as including:

Step S21, Build a network architecture of the neural network model based on an Identity block and a Dense block; and

Step S22, According to the proposed network architecture, build the neural network model using Keras library, where when building, the model is compiled using a compile function, MSE is specified as the loss function, Adam is specified as a neural network optimizer, and MSE is specified as the metrics function.

In step S21, the network architecture of the built neural network model of the present application draws on a network architecture of a residual network, and is different from the residual network in that a fully connected layer is adopted in the present application instead of a convolution layer and a pooling layer of the residual network. FIG. 8 schematically shows a network architecture of a machine learning model for CD-SEM measurement according to an implementation of the present disclosure. Referring to FIG. 8, FIG. 8 shows an architecture of an Identity block, an architecture of a Dense block, and an overall network architecture. The overall network architecture is set up as composed of two basic blocks 100, a batch normalization layer, a fully connected layer, and a linear activation function which are connected sequentially, where each basic block 100 is formed by connecting two Identity blocks sequentially after one Dense block. In the present application, the Identity block is set up as composed of three basic units 200 which are connected sequentially, where each basic unit 200 is formed by connecting a fully connected layer, a batch normalization layer, and a ReLU activation function sequentially, and a Dropout layer is inserted after the second basic unit. In the present application, the Dense block is set up as composed of three basic units which are connected sequentially, where a Dropout layer is inserted after the second basic unit, and a residual path units 300 is connected additionally after each of the first basic unit and the second basic unit. The residual path unit consists of a fully connected layer and a batch normalization layer which are stacked sequentially, and a result between the output of the residual path unit and the batch normalization layer and ReLU activation function of the third basic unit of the Dense block is configured to perform a tensor summation operation. By setting the network architecture of the present disclosure in such a way, when compared with a network architecture of a traditional neural network model, a traditional residual network is more suitable for image processing, and the network architecture of the present disclosure may be more suitable for nonlinear regression after modification and optimization.

In step S22, the implementation of the scheme of the present application is to build the neural network model according to the proposed network architecture, build the neural network model using Keras library Keras is an open-source neural network library, which may run with TensorFlow, CNTK or Theano as the backend. For a detailed introduction related thereto, reference may be made to the related prior art, which will not be repeated here. When building the neural network model, in the present disclosure, the model is compiled using a compile function, MSE is specified as the loss function, Adam is specified as a neural network optimizer, and MSE is specified as the metrics function. The loss function, which is an important concept in machine learning and deep learning, is used to measure a difference or error between the prediction result of the model and the real result. The loss function is a numerical evaluation indicator, and provides metrics of the model performance by comparing the model output with a true label. The main function of an optimizer is to make the gradient descend faster and better in the process of gradient descent, so as to find the minimum value of an objective function as soon as possible, that is, to find the optimal “loss” by what means in the fastest way. The metrics function is used to evaluate the performance of the model during and after training. After the model is compiled (using the compile function), the specified evaluation function is used as a parameter of the metrics function for input. It should be noted that the evaluation function is similar to the loss function. However, the result of the evaluation function will not be used in the training process, and the evaluation function is mainly used to evaluate the accuracy of model prediction. Among the commonly used regression evaluation indicators, the relative error of the model prediction obtained by using MSE as the loss function is relatively small. Specifically, the relative error obtained by using MSE is 4.8%, the relative error obtained by using MAE is 6.3%, and the relative error obtained by using MSLE is 56.6%. For the regression evaluation indicator selected for the metrics function, the same function as the loss function is preferentially selected to observe the training effect more easily.

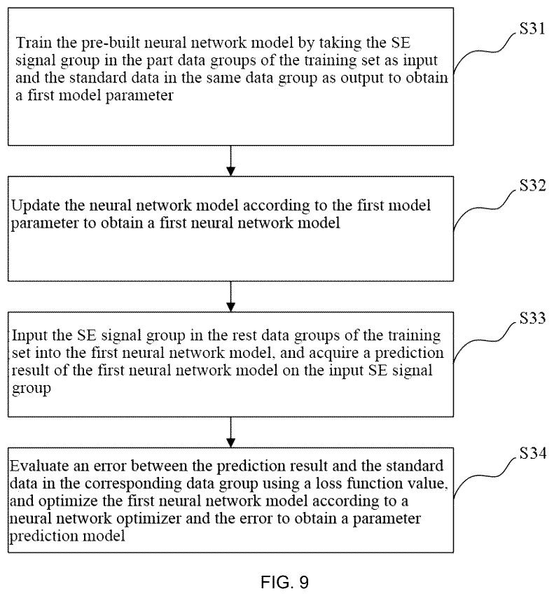

When the pre-built neural network model is trained using the acquired data set, in an implementation of partitioning the data set into a training set and a test set, the neural network model may be trained using the training set. In some possible implementations, before training, the data set may be pre-processed. The pre-processing includes normalizing the data set, especially normalizing data lengths and signal intensities of the SE signal groups of the data set. Normalizing the data set is to avoid the bias of a simulator or an electron microscope itself. Furthermore, data normalization may solve the problem of inconsistent scales of different features, making the influence of different features on the model more balanced. In addition, normalization may also prevent the problem of gradient disappearance or explosion, thus accelerating the convergence speed of the model. For example, normalizing the data lengths and signal intensities of the SE signal groups of the data group may include selecting the maximum length of an SE signal group from all data groups of the data set as a standard length, then filling all SE signal groups with different lengths of the data groups of the data set with data by taking the standard length as a benchmark, to fill the SE signal groups with a length less than the standard length as SE signal groups with the standard length, so that the lengths of the SE signal groups of all the data groups of the data set are the same, and normalizing the signal intensities to a range of [0,1] according to the maximum value and minimum value of each SE signal group itself. When training the neural network model, a fit function may be used for training, epochs, batch_size, and validation_split are specified, and a loss value during training is recorded and the loss value is verified to be a metrics value. In machine learning, the fit function is used to train the model, so that parameters may be adjusted according to the given training data, so as to better adapt to the data; epoch refers to a process in which a complete data set passes through the neural network once and returns once, that is, one epoch is a process in which all training samples are trained once; and batch_size refers to the preset number of samples input into the model simultaneously in each iteration when training the model. Validation_split refers to a floating-point number between 0 and 1, which is used to specify a certain proportion of data in the training set as the validation set. For example, in this embodiment, if it is specified that the part of the training set used to train the built neural network model accounts for 90% and the validation set accounts for the remaining 10%, then validation_split is specified as 0.1. After a parameter prediction model is obtained by training, the parameter prediction model is saved. FIG. 9 schematically shows a specific implementation flow of step S12 according to an implementation of the present disclosure. Referring to FIG. 9, step S12 may be specifically implemented as including:
step S31, Select one or more data groups from the training set, and train the pre-built neural network model by taking the SE signal group in the same data group as input and the standard data in the same data group as output to obtain a first model parameter;
step S32, Update the neural network model according to the first model parameter to obtain a first neural network model;
step S33, Input the SE signal group in the data group of the validation set into the first neural network model, and acquire a prediction result of the first neural network model on the input SE signal group; and
step S34, Evaluate an error between the prediction result and the standard data in the corresponding data group using a loss function value, and optimize the first neural network model according to the neural network optimizer and the error to obtain a parameter prediction model.

In step S31, the preset number of samples input into the model simultaneously may be determined by the specified batch_size value, and the preset number of times of training may be determined by the specified epoch value. According to the specified batch_size value and epoch value, the pre-built neural network model is trained by taking the SE signal group in the same data group as input and the standard data in the same data group as output, so that a corresponding first model parameter of the trained neural network model may be obtained.

In step S32, the first neural network model is generated based on the first model parameter. In step S33, the input data, that is, the SE signal group, in the data group of the validation set is input into the first neural network model, so that a corresponding prediction result output by the first neural network model may be obtained.

In step S34, the first neural network model is optimized based on the prediction result and the standard data. Specifically, an error between the prediction result output by the first neural network model and the corresponding standard data may be determined using the loss function specified when building the neural network model. After the error is obtained, the first neural network model is optimized according to the error and the optimizer Adam specified when building the neural network model, so that the parameter prediction model may be obtained based on the optimization result. It can be understood that the parameter prediction model obtained by training also has the network architecture as shown in FIG. 8.

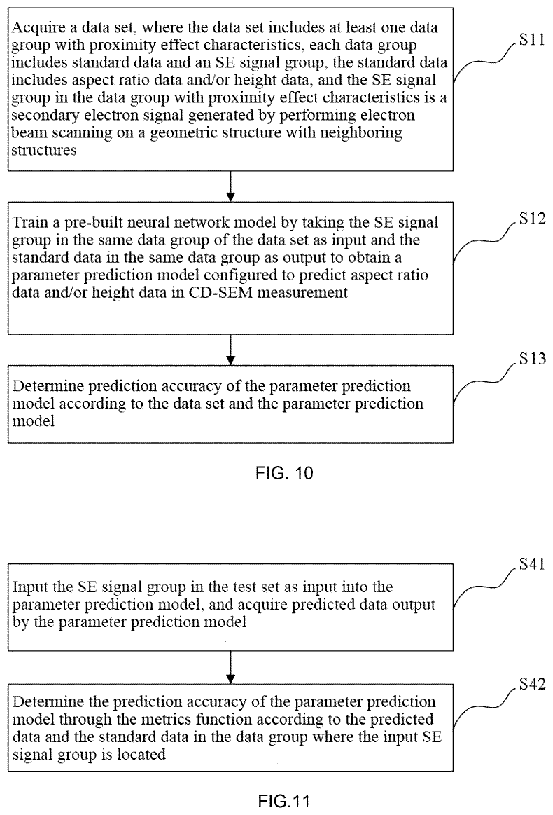

FIG. 10 schematically shows an overall flow of a machine learning model training method for CD-SEM measurement according to another implementation of the present disclosure. The method may be performed by a computing device such as a computer and a server, to train a parameter prediction model for CD-SEM measurement by means of the method. Referring to FIG. 10, based on the method shown in FIG. 1, the machine learning model training method for CD-SEM measurement of the present disclosure may further include:

Step S13, Determine prediction accuracy of the parameter prediction model according to the data set and the parameter prediction model.

In step S13, in an embodiment of the present disclosure, the prediction accuracy of the parameter prediction model obtained by training may be further measured, and a reference value of the prediction result may be clarified by determining the prediction accuracy. FIG. 11 schematically shows a specific implementation flow of step S13 in a machine learning model training method for CD-SEM measurement according to an implementation of the present disclosure. Referring to FIG. 11, step S13 may be specifically implemented as including:
step S41, Input the SE signal group in the test set as input data into the parameter prediction model, and acquire predicted data output by the parameter prediction model; and
step S42, Determine the prediction accuracy of the parameter prediction model through the metrics function according to the predicted data and the standard data in the data group where the input SE signal group is located.

Step S41 is a step of performing simulation prediction using the parameter prediction model. Specifically, in step S41, simulation prediction may be performed using a test set, and predicted data may be determined by taking the SE signal group in the test set as input of the parameter prediction model. The predicted data includes a predicted aspect ratio and/or a predicted height.

Step S42 is a step of calculating a mean square error between the predicted data and the corresponding standard data according to the predicted data and the corresponding standard data. Specifically, the mean square error may be calculated based on the metrics function specified when building the neural network model, so that the error rate of the two may be calculated. Specifically, based on the predicted data and the standard data in the data group where the input SE signal group is located, corresponding scatter diagrams of the standard data and the predicted data, as well as distribution diagrams of predicted data errors may be derived to form visual data, to facilitate comparison and observation.

For example, an overall flow of a parameter prediction model building method for CD-SEM measurement is illustratively shown next. When building the network architecture and neural network model, codes for data processing, deep learning model architecture design, training, verification and test are all compiled in Python programming language in this process, and Keras is realized using the advanced API of TensorFlow. In the training process, MSE is used as the training and verification loss, and the MSE formula is as follows:

$$loss = \frac{1}{n} \text{?} {( {y}_{k} - {\hat{y}}_{k} )}^{2}$$

$$\text{?} \text{indicates text missing or illegible when filed}$$

The data set used includes 5906 data groups, where by means of random number partitioning, 90% of the data groups is used as the training set, 10% of the data groups is used as the test set, and 10% of the data groups of the training set is used as the validation set. In the data set, bcd ranges from 20 nm to 36 nm, swa ranges from 80° to 90°, h ranges from 48 nm to 144 nm, aspect ratio ranges from 4 to 20, r is fixed at 1 nm, and an electron beam scanning tilt angle is fixed at 2.5°.

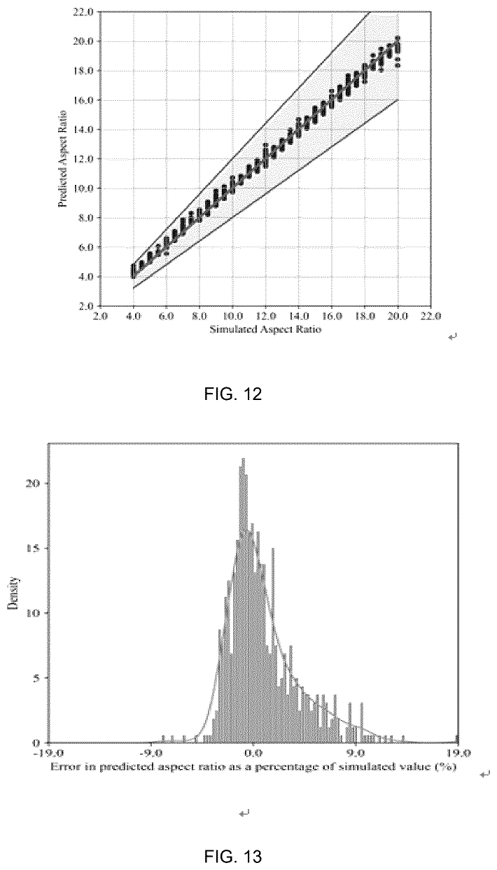

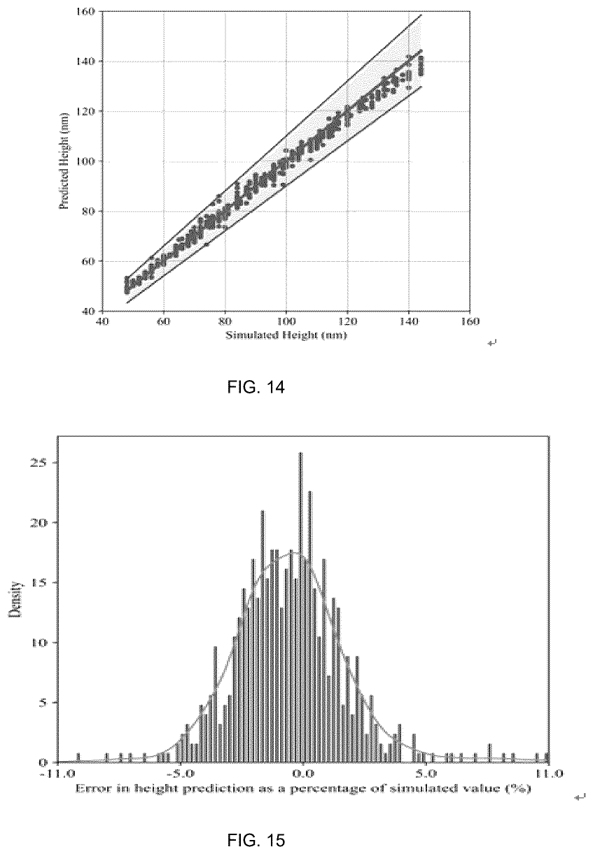

Thereafter, the neural network model may be trained using the training set to obtain the parameter prediction model. The parameter prediction model may be saved after being obtained, and the prediction accuracy of the parameter prediction model may be measured using the test set. Specifically, the measurement results are as shown in FIG. 12 to FIG. 15. FIG. 12 is a scatter diagram showing aspect ratios in standard data and aspect ratios in predicted data, where the shaded part indicates that the relative error is within 20%. FIG. 13 is a distribution diagram showing relative errors between aspect ratios in standard data and aspect ratios in predicted data. FIG. 14 is a scatter diagram showing heights in standard data and heights in predicted data, where the shaded part indicates that the relative error is within 10%. FIG. 15 is a distribution diagram showing relative errors between heights in standard data and heights in predicted data.

### Prediction Result Data:

1. Aspect ratio: the final training loss and verification loss are 0.0052 and 0.00035, respectively, and the loss of the test set is 0.00036. The Root Mean Square Error (RMSE) of the test loss is 0.0190. By testing the test set (10% of the data set), the mean relative error between the predicted data and the standard data is 2.4%, and the percentage of predicted cases with an error within 20% is 100.0%.

Height: the final training loss and verification loss are 0.0052 and 0.00067, respectively, and the loss of the test set is 0.00068. The Root Mean Square Error (RMSE) of the test loss is 0.0262. By testing the test set (10% of the data set), the mean relative error between the predicted data and the standard data is 1.9%, and the percentage of predicted cases with an error within 10% is 99.5%.

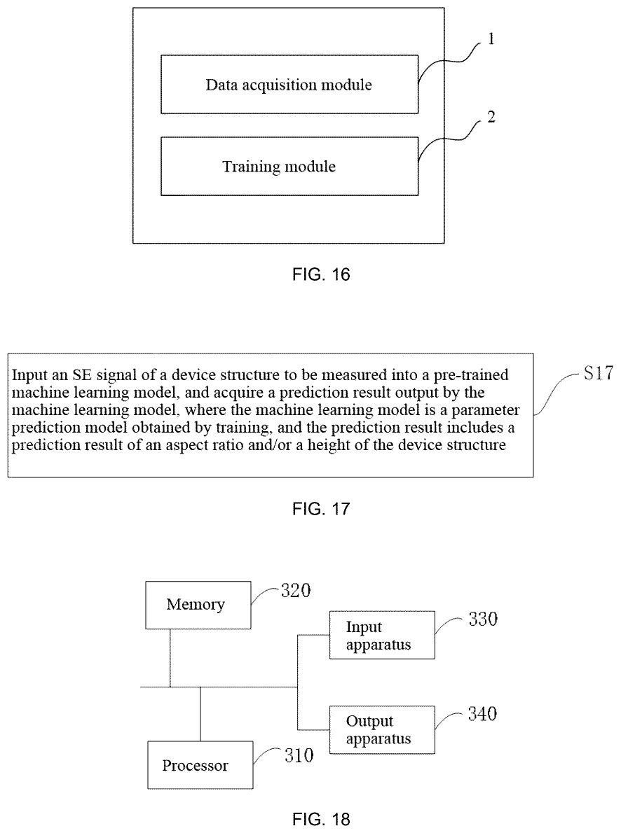

FIG. 16 is a schematic block diagram schematically showing a machine learning model training apparatus for CD-SEM measurement according to an implementation of the present disclosure. Referring to FIG. 16, the parameter prediction model training apparatus for CD-SEM measurement of the present disclosure includes:
a data acquisition module 1, configured to acquire a data set, where the data set includes at least one data group with proximity effect characteristics, each data group includes standard data and an SE signal group, the standard data includes aspect ratio data and/or height data, and the SE signal group in the data group with proximity effect characteristics is a secondary electron signal generated by performing electron beam scanning on a geometric structure with neighboring structures; and
a training module 2, configured to train a pre-built neural network model by taking the SE signal group in the same data group of the data set as input and the standard data in the same data group as output to obtain a parameter prediction model configured to predict aspect ratio data and/or height data in CD-SEM measurement.

It should be noted that for the implementation process and implementation principle of the parameter prediction model training apparatus for CD-SEM measurement in an embodiment of the present disclosure, reference is made to the corresponding description of the above-mentioned method embodiments in detail, such as the corresponding description of the acquisition of the data set and the training of the model in the method embodiments, which will not be repeated here. For example, the parameter prediction model training apparatus for CD-SEM measurement in an embodiment of the present disclosure may be any intelligent computing device with a processor, including but not limited to a computer, a smart phone, a personal computer, a robot, a cloud server, etc.

The present disclosure further provides a parameter prediction method for CD-SEM measurement. In the method, an aspect ratio and/or a height of a device structure is predicted using the parameter prediction model obtained by means of the machine learning model training method for CD-SEM measurement described in any of the above embodiments and an SE signal of the device structure to be measured. Specifically, as shown in FIG. 17, in the method, an SE signal of a device structure to be measured is input into the parameter prediction model in S17, so that an aspect ratio and/or a height of the device structure may be predicted. The processor of any intelligent computing device such as a computer, a smart phone, a personal computer, a robot, and a cloud server may perform the method process described in FIG. 17. Compared with the method in the prior art, in the prediction method of the present application, there is no need to modify a hardware structure of a CD-SEM, thus avoiding problem of complicating the hardware structure and also avoiding the problem of affecting the reliability, and there is no need to adjust operation parameters of the CD-SEM, so that a sample will not be damaged and the quality of a detection mage will not be affected. Moreover, the parameter prediction model of the present disclosure considers the influence of proximity effects, so that the prediction accuracy is very high, and the application scenarios are wider.

The present disclosure further provides a parameter prediction system for CD-SEM measurement. The system includes a prediction module configured to predict an aspect ratio and/or a height of a device structure according to an SE signal of the device structure to be measured and the parameter prediction model obtained by means of the machine learning model training method for CD-SEM measurement described in any of the above embodiments.

In some embodiments, an embodiment of the present disclosure provides a non-volatile computer-readable storage medium storing one or more programs including execution instructions. The execution instructions may be read and executed by an electronic device (including but not limited to a computer, a server, or a network device, etc.) to perform the machine learning model training method for CD-SEM measurement or the parameter prediction method for CD-SEM measurement in any of the above embodiments of the present disclosure.

In some embodiments, an embodiment of the present disclosure further provides a computer program product including a computer program stored in a non-volatile computer-readable storage medium. The computer program includes program instructions which, when executed by a computer, cause the computer to perform the machine learning model training method for CD-SEM measurement or the parameter prediction method for CD-SEM measurement in any of the above embodiments.

In some embodiments, an embodiment of the present disclosure further provides an electronic device including at least one processor and a memory in communication connection with the at least one processor. The memory stores instructions executable by the at least one processor. The instructions, when executed by the at least one processor, cause the at least one processor to perform the machine learning model training method for CD-SEM measurement or the parameter prediction method for CD-SEM measurement in any of the above embodiments.

In some embodiments, an embodiment of the present disclosure further provides a storage medium storing a computer program thereon. The computer program, when executed by a processor, implements the machine learning model training method for CD-SEM measurement or the parameter prediction method for CD-SEM measurement in any of the above embodiments.

FIG. 18 is a hardware structural schematic diagram of a computing device for performing a machine learning model training method for CD-SEM measurement or a parameter prediction method for CD-SEM measurement provided by another embodiment of the present disclosure. As shown in FIG. 18, the device includes:

one or more processors 310 and a memory 320. One processor 310 is taken as an example in FIG. 18.

The device for performing the machine learning model training method for CD-SEM measurement or the parameter prediction method for CD-SEM measurement may further include: an input apparatus 330 and an output apparatus 340.

The processor 310, the memory 320, the input apparatus 330, and the output apparatus 340 may be connected by means of a bus or in other means. The connection by means of a bus is taken as an example in FIG. 18.

The memory 320, as a non-volatile computer-readable storage medium, may be used to store non-volatile software programs, non-volatile computer-executable programs and modules, such as program instructions/modules corresponding to the machine learning model training method for CD-SEM measurement or the parameter prediction method for CD-SEM measurement in the embodiments of the present application. The processor 310 executes various function applications and data processing of the server by running the non-volatile software programs, instructions and modules stored in the memory 320, that is, implements the machine learning model training method for CD-SEM measurement or the parameter prediction method for CD-SEM measurement in the above method embodiments.

The memory 320 may include a program storage area and a data storage area. The program storage area may store an operating system, and an application required by at least one function; and the data storage area may store data, etc. created by use of the machine learning model training method for CD-SEM measurement or the parameter prediction method for CD-SEM measurement. In addition, the memory 320 may include a high-speed random access memory, and may also include a non-volatile memory, such as at least one magnetic disk storage device, a flash memory device, or other non-volatile solid state storage device. In some embodiments, the memory 320 optionally includes memories remotely located with respect to the processor 310, and these remote memories may be connected to the electronic device through networks. Examples of the above networks include, but are not limited to, the Internet, an intranet, a local area network, a mobile communication network, and a combination thereof.

The input apparatus 330 may receive input digit or character information and generate signals related to user settings and function control of an image processing device. The output apparatus 340 may include a display device, such as a display screen.

The one or more modules are stored in the memory 320, which, when executed by the one or more processors 310, perform the machine learning model training method for CD-SEM measurement or the parameter prediction method for CD-SEM measurement in any of the above method embodiments.

The above product may perform the method provided in an embodiment of the present application, and has corresponding functional modules and beneficial effects for performing the method. For technical details not described in detail in this embodiment, reference is made to the method provided by the embodiment of the present application.

The computing device of an embodiment of the present application exists in various forms, including but not limited to:
(1) Mobile communication devices: such devices are characterized by having a mobile communication function, and having a main goal of providing voice and data communication. Such terminals include a smart phone (such as an iPhone), a multimedia phone, a functional phone, a low-end phone, etc.
(2) Ultra-mobile personal computer devices: such devices belong to the category of personal computers, and have computing and processing functions, as well as mobile internet access characteristics in general. Such terminals include PDA, MID and UMPC devices, etc., such as an iPad.
(3) Portable entertainment devices: such devices may display and play multimedia content, and include: an audio or video player (such as an iPod), a handheld game machine, an e-book, as well as a smart toy and a portable car navigation device.
(4) Servers: devices that provide computing services. The servers consist of a processor, a hard disk, a memory, a system bus, etc. The servers are similar to a general-purpose computer in architecture, but require high processing capacity, stability, reliability, security, scalability and manageability due to the need to provide highly reliable services.
(5) Other electronic apparatuses with data interaction functions.

The apparatus embodiments described above are merely illustrative, in which the units described as separate components may or may not be physically separated, and the components displayed as units may or may not be physical units, that is, may be located in one place, or may be distributed onto a plurality of network elements. Some or all of the modules may be selected according to actual needs to achieve the objective of the scheme in this embodiment.

Through the description of the above implementations, those skilled in the art can clearly understand that each implementation may be achieved by means of software in conjunction with a common hardware platform, and certainly, may be achieved by hardware. Based on this understanding, the above technical scheme essentially or the part that contributes to the related technology can be embodied in the form of a software product. The computer software product may be stored in a computer-readable storage medium such as ROM/RAM, a magnetic disk, or an optical disk, and includes several instructions for instructing a computer device (which may be a personal computer, a server, or a network device, etc.) to perform the method described in various embodiments or certain parts of the embodiments.

Finally, it should be noted that: the above embodiments are only used to explain the technical schemes of the present application, rather than limiting same. Although the present application is described in detail with reference to the foregoing embodiments, it will be understood by those of ordinarily skill in the art that modifications may be made to the technical schemes described in the foregoing embodiments, or equivalent replacements may be made to some of the technical features thereof. These modifications or replacements do not make the essence of corresponding technical schemes depart from spirit and scope of technical schemes of the embodiments of the present application.

What is claimed is:

1. A machine learning model training method performed by a computer device, wherein a trained machine learning model is called a parameter prediction model configured to perform parameter prediction in CD-SEM measurement, the method comprising:
acquiring a data set, wherein the data set comprises at least one data group with proximity effect characteristics, each data group comprises standard data and an SE signal group, the standard data comprises aspect ratio data and/or height data, and the SE signal group in the data group with proximity effect characteristics is a secondary electron signal generated by performing electron beam scanning on a geometric structure with neighboring structures; and
training a pre-built neural network model by taking the SE signal group in the same data group of the data set as input and the standard data in the same data group as output to obtain a parameter prediction model configured to predict aspect ratio data and/or height data in CD-SEMmeasurement.

2. The method according to claim 1, further comprising: building the neural network model by performing the following processes by the computer device:
building a network architecture of the neural network model based on an Identity block and a Dense block; and
building, according to proposed network architecture, the neural network model using Keras library, where when building, the model is compiled using a compile function, MSE is specified as a loss function, Adam is specified as a neural network optimizer, and MSE is specified as a metrics function.

3. The method according to claim 2, wherein the network architecture of the neural network model is set up as composed of two basic blocks, a batch normalization layer, a fully connected layer, and a linear activation function which are connected sequentially, wherein each basic block is formed by connecting two Identity blocks sequentially after one Dense block;
the Identity block comprises three basic units which are connected sequentially, wherein each basic unit is formed by connecting a fully connected layer, a batch normalization layer, and a ReLU activation function sequentially, and a Dropout layer is inserted after a second basic unit; and
the Dense block comprises three basic units which are connected sequentially, wherein a Dropout layer is inserted after the second basic unit, and a residual path unit is connected additionally after each of a first basic unit and the second basic unit, wherein the residual path unit consists of a fully connected layer and a batch normalization layer which are stacked sequentially, and a result between the output of the residual path unit and the batch normalization layer and ReLU activation function of a third basic unit of the Dense block is configured to perform a tensor summation operation.

4. The method according to claim 1, wherein the data set is obtained by performing SEM simulation imaging on a simulation-built geometric structure with neighboring structures, wherein the standard data in each data group of the data set is obtained based on parameter information about the simulation-built geometric structure, and the SE signal is obtained based on parameter information about the simulation imaging.

5. The method according to claim 1, wherein the data set comprises a training set and a test set which are obtained by performing random number partitioning on a plurality of data groups of the data set; and
when training, a built neural network model is trained using part data groups of the training set to acquire model parameters, and the acquired model parameters are optimized using the rest data groups of the training set.

6. The method according to claim 5, wherein the training a pre-built neural network model by taking the SE signal group in the same data group of the data set as input and the standard data in the same data group as output to obtain a parameter prediction model comprises:
training the pre-built neural network model by taking the SE signal group in the part data groups of the training set as input and the standard data in the same data group as output to obtain a first model parameter;
updating the neural network model according to the first model parameter to obtain a first neural network model;
inputting the SE signal group in the rest data groups of the training set into the first neural network model, and acquiring a prediction result of the first neural network model on the input SE signal group; and
evaluating an error between the prediction result and the standard data in the corresponding data group using a loss function value, and optimizing the first neural network model according to a neural network optimizer and the error to obtain a parameter prediction model.

7. The method according to claim 5, further comprising: determining prediction accuracy of the parameter prediction model according to the data set and the parameter prediction model, comprising:
inputting the SE signal group in the test set as input into the parameter prediction model, and acquiring predicted data output by the parameter prediction model; and
determining the prediction accuracy of the parameter prediction model through a metrics function according to the predicted data and the standard data in the data group where the input SE signal group is located.

8. The method according to claim 1, further comprising: normalizing data lengths and signal intensities of the SE signal groups of the data groups of the data set before training.

9. A computing device, comprising:
a memory, configured to store executable instructions; and
a processor, configured to execute the executable instructions stored in the memory, wherein the executable instructions, when executed by the processor, perform the following machine learning model training method:
acquiring a data set, wherein the data set comprises at least one data group with proximity effect characteristics, each data group comprises standard data and an SE signal group, the standard data comprises aspect ratio data and/or height data, and the SE signal group in the data group with proximity effect characteristics is a secondary electron signal generated by performing electron beam scanning on a geometric structure with neighboring structures; and
training a pre-built neural network model by taking the SE signal group in the same data group of the data set as input and the standard data in the same data group as output to obtain a parameter prediction model configured to predict aspect ratio data and/or height data in CD-SEMmeasurement.

10. The computing device according to claim 9, wherein a network architecture of the neural network model is set up as composed of two basic blocks, a batch normalization layer, a fully connected layer, and a linear activation function which are connected sequentially, wherein each basic block is formed by connecting two Identity blocks sequentially after one Dense block;
the Identity block comprises three basic units which are connected sequentially, wherein each basic unit is formed by connecting a fully connected layer, a batch normalization layer, and a ReLU activation function sequentially, and a Dropout layer is inserted after a second basic unit; and
the Dense block comprises three basic units which are connected sequentially, wherein a Dropout layer is inserted after the second basic unit, and a residual path unit is connected additionally after each of a first basic unit and the second basic unit, wherein the residual path unit consists of a fully connected layer and a batch normalization layer which are stacked sequentially, and a result between the output of the residual path unit and the batch normalization layer and ReLU activation function of a third basic unit of the Dense block is configured to perform a tensor summation operation.

11. The computing device according to claim 9, wherein the data set is obtained by performing SEM simulation imaging on a simulation-built geometric structure with neighboring structures, wherein the standard data in each data group of the data set is obtained based on parameter information about the simulation-built geometric structure, and the SE signal is obtained based on parameter information about the simulation imaging.

12. The computing device according to claim 9, wherein the executable instructions, when executed by the processor, further perform the following method for building the neural network model:
building a network architecture of the neural network model based on an Identity block and a Dense block; and
building, according to proposed network architecture, the neural network model using Keras library, where when building, the model is compiled using a compile function, MSE is specified as a loss function, Adam is specified as a neural network optimizer, and MSE is specified as a metrics function.

13. The computing device according to claim 9, wherein the data set comprises a training set and a test set which are obtained by performing random number partitioning on a plurality of data groups of the data set; and
when training, a built neural network model is trained using part data groups of the training set to acquire model parameters, and the acquired model parameters are optimized using the rest data groups of the training set.

14. The computing device according to claim 13, wherein the executable instructions, when executed by the processor, further perform the following machine learning model training method:
inputting the SE signal group in the test set as input into the parameter prediction model, and acquiring predicted data output by the parameter prediction model; and
determining a prediction accuracy of the parameter prediction model through a metrics function according to the predicted data and the standard data in the data group where the input SE signal group is located.

15. The computing device according to claim 9, wherein the executable instructions, when executed by the processor, further perform the following machine learning model training method:
normalizing data lengths and signal intensities of the SE signal groups of the data groups of the data set before training.

16. A parameter prediction method for CD-SEM measurement performed by a computer device, comprising:
inputting an SE signal of a device structure to be measured into a pre-trained machine learning model, and acquiring a prediction result output by the machine learning model, wherein the machine learning model is a parameter prediction model trained using the above method of claim 1, and the prediction result comprises a prediction result of an aspect ratio and/or a height of the device structure.

17. The method according to claim 16, wherein a network architecture of the parameter prediction model is set up as composed of two basic blocks, a batch normalization layer, a fully connected layer, and a linear activation function which are connected sequentially, wherein each basic block is formed by connecting two Identity blocks sequentially after one Dense block;
the Identity block comprises three basic units which are connected sequentially, wherein each basic unit is formed by connecting a fully connected layer, a batch normalization layer, and a ReLU activation function sequentially, and a Dropout layer is inserted after a second basic unit; and
the Dense block comprises three basic units which are connected sequentially, wherein a Dropout layer is inserted after the second basic unit, and a residual path unit is connected additionally after each of a first basic unit and the second basic unit, wherein the residual path unit consists of a fully connected layer and a batch normalization layer which are stacked sequentially, and a result between the output of the residual path unit and the batch normalization layer and ReLU activation function of a third basic unit of the Dense block is configured to perform a tensor summation operation.

18. A computing device, comprising:
a memory, configured to store executable instructions; and
a processor, configured to execute the executable instructions stored in the memory, wherein the executable instructions, when executed by the processor, perform the following parameter prediction method for CD-SEM measurement:
inputting an SE signal of a device structure to be measured into a pre-trained machine learning model, and acquiring a prediction result output by the machine learning model, wherein the machine learning model is a parameter prediction model obtained by training using the above method of claim 1, and the prediction result comprises a prediction result of an aspect ratio and/or a height of the device structure.

19. The computing device according to claim 18, wherein a network architecture of the parameter prediction model is set up as composed of two basic blocks, a batch normalization layer, a fully connected layer, and a linear activation function which are connected sequentially, wherein each basic block is formed by connecting two Identity blocks sequentially after one Dense block;
the Identity block comprises three basic units which are connected sequentially, wherein each basic unit is formed by connecting a fully connected layer, a batch normalization layer, and a ReLU activation function sequentially, and a Dropout layer is inserted after a second basic unit; and
the Dense block comprises three basic units which are connected sequentially, wherein a Dropout layer is inserted after the second basic unit, and a residual path unit is connected additionally after each of a first basic unit and the second basic unit, wherein the residual path unit consists of a fully connected layer and a batch normalization layer which are stacked sequentially, and a result between the output of the residual path unit and the batch normalization layer and ReLU activation function of a third basic unit of the Dense block is configured to perform a tensor summation operation.
